(19) United States
(12) Patent Application Publication
(10) Pub. No.: US 2024/0162246 A1
(43) Pub. Date: May 16, 2024

(54) ARRAY SUBSTRATE, MANUFACTURING METHOD THEREOF, AND DISPLAY PANEL

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventor: Yanhong Meng, Guangzhou, Guangdong (CN)

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/756,662

(22) PCT Filed: May 13, 2022
(86) PCT No.: PCT/CN2022/092758

§ 371 Date: May 30, 2022

(30) Foreign Application Priority Data
May 6, 2022 (CN) 202210484423.X

(51) Int. Cl. H01L 27/12; G02F 1/1362

(52) U.S. Cl. CPC H01L 27/1248; G02F 1/136227; G02F 1/136286; H01L 27/1288; H01L 27/1225

(57) ABSTRACT

An array substrate, a manufacturing method thereof, and a display panel thereof are disclosed. The array substrate includes: an underlay; a first insulation layer; a first active layer; a protective layer; a first gate electrode disposed on the first active layer at an interval from the protective layer; a second insulation layer; and a first source electrode and a first drain electrode, wherein the first source electrode and the first drain electrode are connected to the protective layer through first via holes in the second insulation layer; wherein a material of the protective layer includes indium tin oxide or indium gallium zinc oxide.

The present application claims the benefit of a priority of a CN patent application No. 202210484423.X filed with the China national intellectual property administration (CNIPA) on May 6, 2022, titled “ARRAY SUBSTRATE, MANUFACTURING METHOD THEREOF AND DISPLAY PANEL”, which is hereby incorporated by reference.

### FIELD OF INVENTION

The present application relates to a field of display technologies, especially to an array substrate, a manufacturing method thereof, and a display panel.

### BACKGROUND OF INVENTION

A low-temperature polycrystalline silicon (LTPS) is a liquid crystal display technology extensively applied to medium and small electronic products such as tablets and mobile communication apparatuses. Compared to a conventional amorphous silicon liquid crystal display device, the low-temperature polycrystalline silicon liquid crystal display device has many advantages such as high resolution, fast responsive speed, large aperture rate, high display brightness. Also, the low-temperature polycrystalline silicon liquid crystal display device can also manufacture a peripheral driver circuit on a glass substrate, which facilitates reduction of connecting assemblies and can save a space and a production cost and improve reliability and stability of products. Metal oxide has an advantages of low leakage current and low-temperature polycrystalline silicon and metal oxide can be combined to form a low-temperature polycrystalline silicon oxide (LTPO).

However, because an LTPO semiconductor device has a small volume and high integration, the entire LTPO array substrate has a complicated manufacturing process, and a long production cycle. Also, etching of each step is difficult to control such that an error of processing each film layer is increased. A broken circuit has great influence to performance of a LTPO array substrate, and over-etching is a main factor causing a broken circuit of source and drain electrodes of the LTPO semiconductor device. At present, via hole processing requires multiple etching processes to source and drain electrodes, and both excessive and insufficient amounts of etching increase a contact resistance between a pixel electrode and the source and drain electrodes. Completely etching and removing the source and drain electrodes would cause failure of the array substrate.

Therefore, the conventional technology has defects and requires improvement and development.

### SUMMARY OF INVENTION

### Technical Issue

The present application provides an array substrate and a manufacturing method thereof, display panel to increase transmittance of the display panel and improve the yield rate and reliability of the display panel.

### Technical Solution

To solve the above issue, the present application provides an array substrate including: an underlay; a first insulation layer disposed on the underlay; a first active layer disposed on the first insulation layer; a protective layer disposed on the first active layer; a first gate electrode disposed on the first active layer and disposed at an interval from the protective layer; a second insulation layer disposed on the first insulation layer, the first active layer, the protective layer, and the first gate electrode; and a first source electrode and a first drain electrode, wherein the first source electrode and the first drain electrode are connected to the protective layer through first via holes defined in the second insulation layer; wherein a material of the protective layer includes indium tin oxide or indium gallium zinc oxide.

The array substrate further includes:
a second active layer disposed on the underlay, wherein the first insulation layer covers the second active layer;
a second gate electrode corresponding to the second active layer and disposed in the first insulation layer; and
a second source electrode and a second drain electrode, wherein the second source electrode and the second drain electrode are connected to the second active layer through second via holes defined in the second insulation layer and the first insulation layer, and the second gate electrode are located between the second source electrode and the second drain electrode.

The array substrate further includes:
a first dielectric layer, a first conductive layer, a second dielectric layer, and a second conductive layer sequentially disposed on the first insulation layer, wherein the first conductive layer, the second dielectric layer, and the second conductive layer are located between the second source electrode and the second drain electrode;
wherein projections of the first conductive layer, the second dielectric layer, and the second conductive layer on the underlay at least partially overlap with one another, and a material of the first conductive layer includes transparent conductive metal oxide.

The array substrate further includes a first gate electrode insulation layer, the first gate electrode insulation layer is disposed between the first gate electrode and the first active layer, the first dielectric layer and the first active layer are disposed in a same layer, the first conductive layer and the protective layer are disposed in a same layer, the second dielectric layer and the first gate electrode insulation layer are disposed in a same layer, and the second conductive layer and the first gate electrode are disposed in a same layer.

A material of the first active layer includes indium tin oxide or indium gallium zinc oxide.

A projection of the first via holes on the underlay is located within a projection of the protective layer on the underlay.

A material of the second active layer includes low temperature polycrystalline oxide.

An organic layer, an inorganic layer, and a first buffer layer are sequentially disposed on the underlay and are located between the underlay and the second active layer.

The first insulation layer includes a gate electrode insulation layer, an interlayer insulation layer, and a second buffer layer.

To solve the above issue, the present application provides an array substrate manufacturing method including: providing an underlay; forming a first insulation layer on the underlay; forming an oxide semiconductor layer on the first insulation layer; forming a transparent conductive layer on the oxide semiconductor layer, wherein a material of the transparent conductive layer includes indium tin oxide or indium gallium zinc oxide; forming a photoresist layer on the transparent conductive layer, and patterning the photoresist layer to form at least one first aperture; and
etching and removing a portion of the transparent conductive layer corresponding to a location of the first aperture to form a protective layer.

The first insulation layer includes a gate electrode insulation layer and an interlayer insulation layer, before the step of forming the first insulation layer on the underlay, the method further includes: forming a second active layer on the underlay;
the step of forming the first insulation layer on the underlay includes:
forming a gate electrode insulation layer on the second active layer;
forming a second gate electrode on the gate electrode insulation layer; and
forming an interlayer insulation layer on the second gate electrode.

Before the step of patterning the photoresist layer to form the at least one first aperture, the method further includes:
patterning the photoresist layer to form at least one second aperture and a plurality of third apertures;
etching and removing portions of the transparent conductive layer corresponding to the at least one second aperture and the third apertures respectively to form a first conductive layer and a first metal layer; and
etching and removing portions of the oxide semiconductor layer corresponding to the at least one second aperture and the third apertures respectively to form a first active layer and a first dielectric layer, wherein the first dielectric layer and a first conductive layer layer are stacked and disposed on the underlay, and the first active layer and the first metal layer layer are stacked and disposed on the underlay.

The step of wet-etching and removing the transparent conductive layer and the step of wet-etching and removing the oxide semiconductor layer are implemented simultaneously, a material of the oxide semiconductor layer includes indium tin oxide or indium gallium zinc oxide, and an etchant for the wet-etching includes oxalic acid.

The step of patterning the photoresist layer to form the at least one first aperture includes:
patterning the photoresist layer, removing the photoresist layer on the first conductive layer, and partially removing the photoresist layer on the first metal layer to form the first aperture.

The method further includes:
forming a third insulation layer on the protective layer and the first conductive layer and patterning the third insulation layer to form a second dielectric layer and a first gate electrode insulation layer, wherein the second dielectric layer at least partially overlaps with the first conductive layer, and the first gate electrode insulation layer is located among the protective layer; and
forming a second metal layer on the first gate electrode insulation layer and the second dielectric layer and patterning the second metal layer to form a first gate electrode and a second conductive layer, wherein the first gate electrode at least partially overlaps with the first gate electrode insulation layer, and the second conductive layer at least partially overlaps with the second dielectric layer.

The array substrate manufacturing method further includes:
forming a second insulation layer on the first gate electrode and the second conductive layer;
forming first via holes and second via holes in the second insulation layer and the first insulation layer;
forming a third metal layer on the second insulation layer; and
patterning the third metal layer to form a first source electrode, a first drain electrode, a second source electrode, and a second drain electrode;
wherein the first source electrode and the first drain electrode are connected to the protective layer through the first via holes formed in the second insulation layer, and the second source electrode and the second drain electrode are connected to the second active layer through the second via holes formed in the second insulation layer and the first insulation layer.

To solve the above issue, the present application provides a display panel, display panel includes an opposite substrate and any one of the above array substrates, wherein the opposite substrate and the array substrate are disposed oppositely at an interval.

The array substrate further includes:
a second active layer disposed on the underlay, wherein the first insulation layer covers the second active layer;
a second gate electrode corresponding to the second active layer and disposed in the first insulation layer; and
a second source electrode and a second drain electrode, wherein the second source electrode and the second drain electrode are connected to the second active layer through second via holes defined in the second insulation layer and the first insulation layer, and the second gate electrode are located between the second source electrode and the second drain electrode.

The array substrate further includes:
a first dielectric layer, a first conductive layer, a second dielectric layer, and a second conductive layer sequentially disposed on the first insulation layer, wherein the first conductive layer, the second dielectric layer, and the second conductive layer are located between the second source electrode and the second drain electrode;
wherein projections of the first conductive layer, the second dielectric layer, and the second conductive layer on the underlay at least partially overlap with one another, and a material of the first conductive layer includes transparent conductive metal oxide.

The array substrate further includes a first gate electrode insulation layer, the first gate electrode insulation layer is disposed between the first gate electrode and the first active layer, the first dielectric layer and the first active layer are disposed in a same layer, the first conductive layer and the protective layer are disposed in a same layer, the second dielectric layer and the first gate electrode insulation layer are disposed in a same layer, and the second conductive layer and the first gate electrode are disposed in a same layer.

### Advantages

Advantages of the present application are as follows: distinguishing from the conventional technology, the present application provides an array substrate, manufacturing method thereof, and a display panel thereof. The array substrate includes: an underlay; a first insulation layer disposed on the underlay; a first active layer disposed on the first insulation layer; a protective layer disposed on the first active layer; a first gate electrode disposed on the first active layer and disposed at an interval from the protective layer; a second insulation layer disposed on the first insulation layer, the first active layer, the protective layer, and the first gate electrode; and a first source electrode and a first drain electrode, wherein the first source electrode and the first drain electrode are connected to the protective layer through first via holes defined in the second insulation layer; wherein a material of the protective layer includes indium tin oxide or indium gallium zinc oxide. Disposing a transparent protective layer on the first active layer can protect the first active layer during later formation of first via holes to improve yield rate reliability of the display panel. Also, using the transparent protective layer can improve transmittance of the display panel.

### DESCRIPTION OF DRAWINGS

FIG. 1 is a schematic flowchart of an array substrate provided by the embodiment of the present application;

FIGS. 2a-2h are schematic structural views corresponding to steps of a manufacturing method provided by the embodiment of the present application; and

FIG. 3 is a schematic structural view of a display panel provided by the embodiment of the present application.

### DETAILED DESCRIPTION OF PREFERRED EMBODIMENTS

Specific embodiments of the present invention are described in details with accompanying drawings as follows. Particularly, the following embodiments are only for explaining the present application but has no limit to a range of the present application. Similarly, the following embodiments are some of the embodiments of the present application but are not all embodiments. All other embodiments obtained by those skilled in the art without making any creative effort shall fall within the protection scope of the present application.

Furthermore, terminologies “first”, “second”, “third”, etc. mentioned by the present application can be can be used to describe various elements. However, such elements should not be limited by these terminologies. These terminologies are merely used to distinguish these elements from one another. For example, under a prerequisite without departing from the present application range, first can be called second, and similarly, second can be called first. Therefore, the used terminology is configured to explain and understand the present application instead of limiting the present application. In each of the attached drawings, units with similar structures use the same reference character of the attached drawings. For clarity, each part of the attached drawings is not drawn in a proportion. Furthermore, some known parts are probably not shown in the attached drawings.

Furthermore, in each of the attached drawings, units with similar structures use the same reference character of the attached drawings. When an assembly is described as “connected to” another assembly, both can be understood to be directly “connected”, or one assembly is indirectly “connected to” another assembly through an intervening assembly.

To make objectives, technical solutions, and advantages of the present application more clear, the present application is described in detail combining the attached drawings as follows.

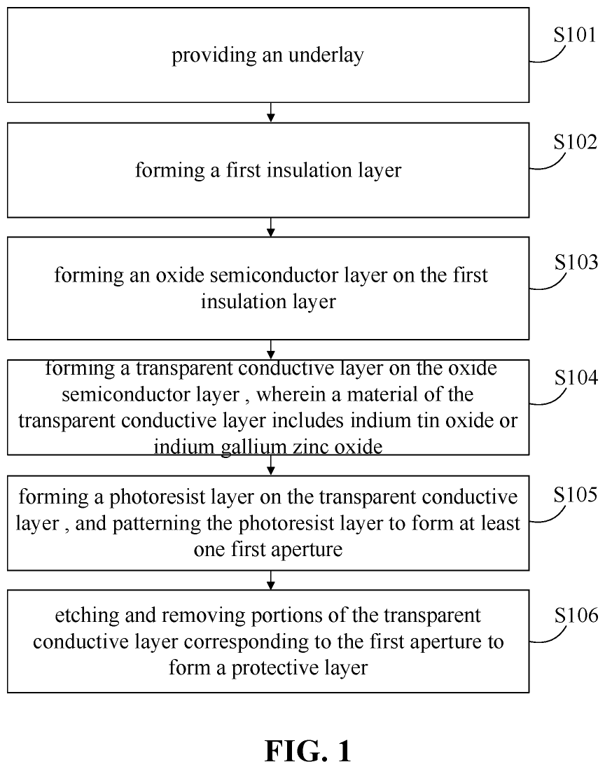

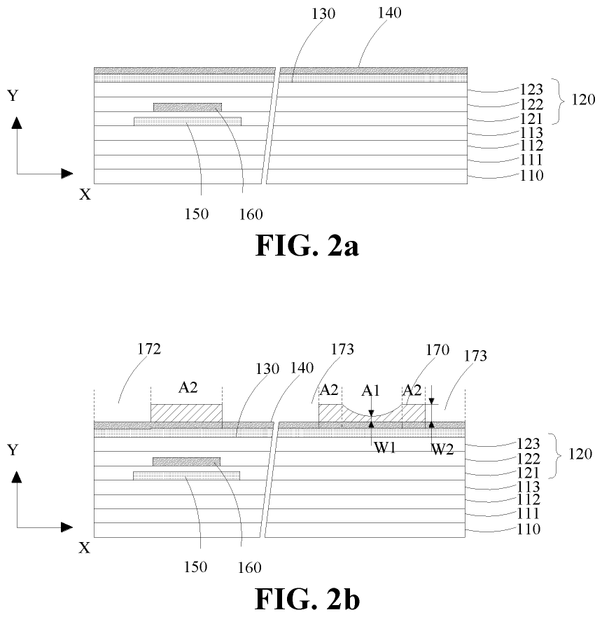

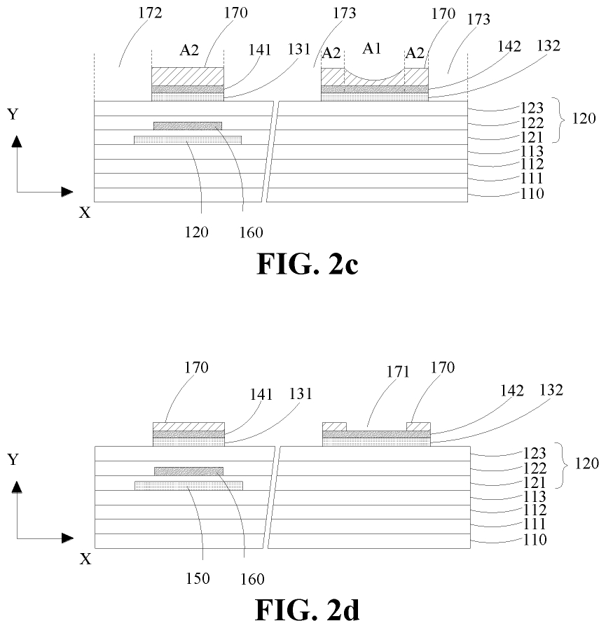

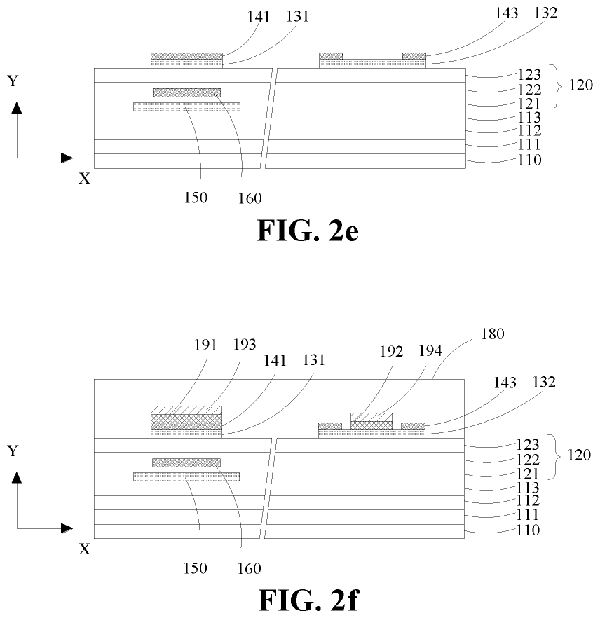

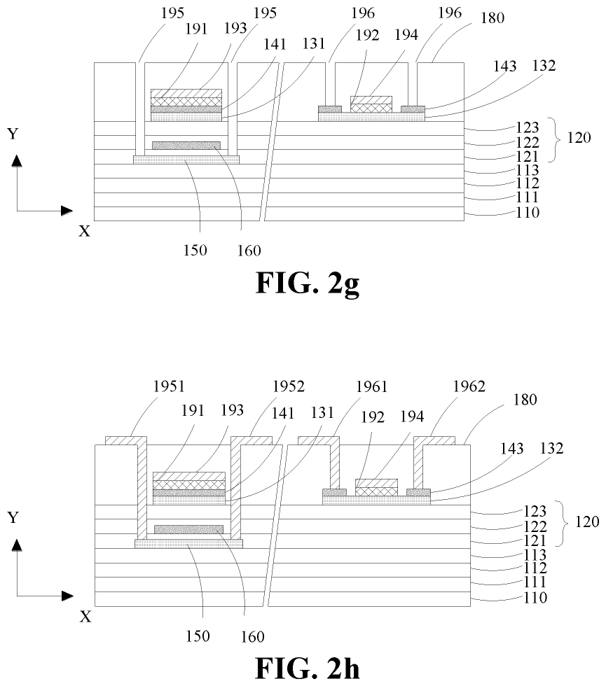

With reference to FIG. 1, the present application provides an array substrate manufacturing method, the array substrate manufacturing method corresponds to structural views of FIGS. 2a to 2h, specific steps are as follows:

A Step S101 includes: providing an underlay 110.

A step S102 includes: forming a first insulation layer 120 on an underlay 110.

A step S103 includes: forming an oxide semiconductor layer 130 on the first insulation layer 120.

A step S104 includes: forming a transparent conductive layer 140 on the oxide semiconductor layer 130, wherein a material of the transparent conductive layer 140 includes indium tin oxide or indium gallium zinc oxide.

The first insulation layer 120 includes a gate electrode insulation layer 121 and an interlayer insulation layer 122. Before the step S102 of forming the first insulation layer 120 on the underlay 110, the method further includes: forming a second active layer 150 on the underlay 110;

The step of forming the first insulation layer 120 on the underlay 110 includes:
forming a gate electrode insulation layer 121 on the second active layer 150;
forming a second gate electrode 160 on the gate electrode insulation layer 121; and
forming an interlayer insulation layer 122 on the second gate electrode 160.

Particularly, before the step of forming the first insulation layer 120 on the underlay 110, the second active layer 150 can be formed on the underlay 110. The step of forming the first insulation layer 120 can further include forming the gate electrode insulation layer 121, the second gate electrode 160, and the interlayer insulation layer 122 on the second active layer 150. Furthermore, after forming the interlayer insulation layer 122, other film layer, for example, a second buffer layer 123, can be further formed on the interlayer insulation layer 122.

Furthermore, It should be explained that FIGS. 2a to 2h only shows structures related to the embodiment of the present application, the array substrate of the present application can further include other assembly and/or structure for implementing a full function of the array substrate.

FIG. 2a shows structures formed in the step S101 to the step S104, which includes: the underlay 110, the second active layer 150, the first insulation layer 120, the oxide semiconductor layer 130, and the transparent conductive layer 140 sequentially disposed on the underlay 110, and the second gate electrode 160 located in the first insulation layer 120. The first insulation layer 120 includes the gate electrode insulation layer 121, the interlayer insulation layer 122, and the second buffer layer 123.

Particularly, the underlay 110 can be a glass substrate, also can include a glass substrate and one or more thin films on the glass substrate. The one or more thin films can be conductive thin films and/or functional thin films. For example, with reference to FIG. 2a, between the underlay 110 and the second active layer 150, an organic layer 111, an inorganic layer 112, and a first buffer layer 113 sequentially disposed on the underlay 110 can be further included. A material of the second active layer 150 can be a polysilicon (P-Si) material. The first insulation layer 120 has no specific limit. With reference to FIG. 2a, the first insulation layer 120 can include one or more insulation layers. For example, the first insulation layer 120 includes a gate electrode insulation layer 121, an interlayer insulation layer 122, and a second buffer layer 123 sequentially disposed on the underlay 110.

A material of the second active layer 150 includes low temperature polycrystalline oxide.

Particularly, because the low-temperature polycrystalline silicon (LTPS) has advantages of high mobility and fast charge, and the metal oxide semiconductor material has an advantage of low leakage current. Combining these two materials to form a low-temperature polycrystalline silicon oxide (LTPO) can gather advantages of the two semiconductor materials to drastically improve a user' experience to the display panel. Therefore, a material of the second active layer 150 can be low-temperature polycrystalline silicon oxide. Using low-temperature polycrystalline silicon oxide increases an electron mobility of the second active layer 150 and lowers a leakage current of a second transistor corresponding to the second active layer 150 to improve performance of the display panel. A second transistor corresponding to the second active layer 150 can be a driver TFT in the display panel.

A step S105 includes: forming a photoresist layer 170 on the transparent conductive layer 140, and patterning the photoresist layer 170 to form at least one first aperture 171.

Before the step of patterning the photoresist layer 170 to form the at least one first aperture 171, the method further includes:
patterning the photoresist layer 170 to form at least one second aperture 172 and a plurality of third apertures 173;
etching and removing portions of the transparent conductive layer 140 corresponding to the at least one second aperture 172 and the third apertures 173 to form a first conductive layer 141 and a first metal layer 142;
etching and removing portions of the oxide semiconductor layer 130 corresponding to the at least one second aperture 172 and the third apertures 173 to form a first active layer 132 and a first dielectric layer 131, wherein the first dielectric layer 131 and the first conductive layer 141 are stacked on the underlay 110, and the first active layer 132 and the first metal layer 142 layer are stacked on the underlay 110.

FIG. 2b shows the structure forming the second aperture 172 and the third apertures 173, which includes: the underlay 110, the second active layer 150, the first insulation layer 120, the oxide semiconductor layer 130, the transparent conductive layer 140, the photoresist layer 170 sequentially located on the underlay 110, and the second gate electrode 160 located in the first insulation layer 120. The photoresist layer 170 includes the at least one second aperture 172 and the third apertures 173. The photoresist layer 170 further includes a thinning region A1. The thinning region A1 is located between the third apertures 173. A thickness W1 of a portion of the photoresist layer 170 corresponding to the thinning region A1 is less than a thickness W2 of the photoresist layer 170 in other region (for example, A2) including the photoresist layer 170.

Particularly, a halftone process (a lithography process implemented with a halftone mask plate) can be used to form the photoresist layer 170 with different thicknesses on the transparent conductive layer 140. To form the photoresist layer 170 with different film layer thicknesses on the transparent conductive layer 140, a halftone mask plate (Halftone Mask, HTM) can be used. The halftone mask plate is usually disposing a light transmission portions, a translucent portion, and a light shielding portions on transparent substrate. A transmittance of the translucent portion is between the light shielding portions and the light transmission portions. When the halftone mask plate is used to expose a photoresist on the substrate, light is irradiated from the light transmission portions and the translucent portion of the halftone mask plate to the photoresist to implement an exposing process to the photoresist. Then, the exposed photoresist is developed, portions of the photoresist on the substrate corresponding to the light shielding portions, the translucent portion, and the light transmission portions of the halftone mask plate are preserved, partially preserved, and removed completely such that a photoresist layer 170 with different thicknesses can be formed on the same substrate simultaneously. The patterned photoresist layer 170 with different thicknesses can be formed on the transparent conductive layer 140 by providing a halftone mask plate and according to the halftone mask plate. The halftone mask plate includes a plurality of light shielding portions, at least one translucent portion, and a plurality of light transmission portions. The light transmission portions and the at least one second aperture 172 correspond to the third apertures 173. The translucent portion corresponds to the thinning region A1. Furthermore, using the halftone process increases no mask plate (also called photomask), which lowers the cost.

FIG. 2c shows the structure forming the first conductive layer 141, the first metal layer 142, the first active layer 132 and the first dielectric layer 131, which includes: the underlay 110 and the first insulation layer 120 and the photoresist layer 170 sequentially located on the underlay 110; the second active layer 150, the second gate electrode 160, the first dielectric layer 131, and the first conductive layer 141 sequentially located on the underlay 110 and the first insulation layer 120; the first active layer 132 and the remaining transparent conductive layer 140 sequentially located on the underlay 110 and the first insulation layer 120.

Particularly, the photoresist layer 170 is formed on the transparent conductive layer 140. After the photoresist layer 170 includes the at least one second aperture 172 and the third apertures 173, portions of the transparent conductive layer 140 corresponding to the at least one second aperture 172 and the third apertures 173 can be etched and removed to form the first conductive layer 141 and the first metal layer 142. Then, portions of the oxide semiconductor layer corresponding to at least one second aperture and the third apertures are etched and removed to form the first active layer 132 and the first dielectric layer 131. The etching process can be wet-etching, and a part of the transparent conductive layer 140 can be removed by a wet-etching process. Etchant of the wet-etching process includes oxalic acid.

Particularly, because the transparent conductive layer 140 can use a material such as IZO or IGZO, the material can be suitable for an oxalic acid etching process. Compared to removal of other material, for example, removing a metal material requires metal acid (for example, Cu acid or A1 acid), and a cost of oxalic acid is lower than that of metal acid, which lowers the manufacturing cost.

Particularly, after formation of the first conductive layer 141, the first metal layer 142, the first active layer 132, and the first dielectric layer 131, the photoresist layer 170 is patterned to form at least one first aperture 171. Namely, the photoresist layer 170 corresponding to the thinning region A1 is removed to form the first aperture 171. FIG. 2d shows the structure formed by the step S105, which includes: the underlay 110, the second active layer 150, the first insulation layer 120, the first dielectric layer 131, the first conductive layer 141, and the photoresist layer 170 sequentially located on the underlay 110, and the second gate electrode 160 located in the first insulation layer 120; the first active layer 132 and the remaining transparent conductive layer 140 sequentially located on the underlay 110 and the first insulation layer 120. The remaining photoresist layer 170 includes a first aperture 171, a second aperture 172, and a third apertures 173. The first aperture 171 corresponds to the thinning region A1.

Particularly, by a plasma dry degumming process (DRY 02 ashing), the photoresist layer 170 of a certain thickness can be removed. The photoresist layer 170 corresponding to the thinning region A1 is removed to form a first aperture 171 corresponding to the thinning region A1 on the photoresist layer 170. By controlling parameters of the dry degumming process, for example, controlling a work time of the plasma dry degumming process, removing a thickness of the photoresist can be achieved to remove the photoresist layer 170 corresponding to the thinning region A1 while remaining at least a part of the photoresist layer 170 in other region.

A step S106 includes: etching and removing portions of the transparent conductive layer 140 corresponding to the first aperture 171 to form a protective layer 143.

The step of wet-etching and removing the transparent conductive layer 140 and the step of wet-etching and removing the oxide semiconductor layer 130 are implemented simultaneously. A material of the oxide semiconductor layer 130 includes indium tin oxide or indium gallium zinc oxide, and etchant of the wet-etching process includes oxalic acid.

FIG. 2e shows the structure formed by the step S106, which includes: the underlay 110 and the first insulation layer 120 and the remaining photoresist layer 170 sequentially located on the underlay 110; the second active layer 150, the second gate electrode 160, second insulation layer, the first dielectric layer 131, and the first conductive layer 141 sequentially located on the first insulation layer 120; and the first active layer 132 and the protective layer 143 sequentially located on the first insulation layer 120. The protective layer 143 are located on two sides of the thinning region A1. The first conductive layer 141 and the protective layer 143 are disposed in the same layer.

Particularly, after the portion of the photoresist layer 170 corresponding to the thinning region A1 is removed to form the first aperture 171, a portion of the transparent conductive layer 140 corresponding to the first aperture 171 is etched and removed to form the protective layer 143. Simultaneously, portions of the transparent conductive layer 140 corresponding to the at least one second aperture 172 and the third apertures 173 are etched and removed to form the first conductive layer 141. A portion of the transparent conductive layer 140 can be wet-etched and removed according to the second aperture 172 such that the transparent conductive layer 140 located on a corresponding region of the first active layer 132 finally forms the protective layer 143. Disposing the transparent protective layer 143 on the first active layer 132 can protect the first active layer 132 during later formation of the first via holes 196 to improve the yield rate and reliability of the display panel. Also, using the transparent protective layer 143 can improve transmittance of the display panel. Because a material of the transparent conductive layer 140 can be ITO or IGZO, it can be suitable for an oxalic acid etching process. Compared to removal of other material, for example, when a part of the metal material is removed, a cost of oxalic acid is lower than metal acid (for example, Cu acid or A1 acid), which lowers the manufacturing cost.

Particularly, because both the transparent conductive layer 140 and the oxide semiconductor layer 130 can use a material such as IZO or IGZO, the material can be suitable for oxalic acid etching. Compared to removal of other material, for example, when a part of the metal material is removed (for example, a part of the transparent conductive layer 140 is removed, the transparent conductive layer 140 is a metal material), the material of the transparent conductive layer 140 is greatly different from that of the oxide semiconductor layer 130, and the same process cannot be used to remove a part of the transparent conductive layer 140 (for later formation of the protective layer 143) and the oxide semiconductor layer 130 (for later formation of the first active layer 132), and an additional metal acid process is needed. However, removing the transparent conductive layer 140 and the oxide semiconductor layer 130 requires no changing machine and liquid, which reduces production time and improves production efficiency. Also, oxalic acid has a lower cost compared to metal acid (for example, Cu acid or A1 acid), which lowers the manufacturing cost.

Furthermore, because both the protective layer 143 and the first active layer 132 can use a material such as IZO or IGZO, both are transparent conductive metal oxide, which can drastically improve transmittance of the display panel. When both the protective layer 143 and the first active layer 132 uses the material such as IZO or IGZO, the transistor corresponding to the first active layer 132 can achieve full transparency.

Furthermore, after parts of the transparent conductive layer 140 and the oxide semiconductor layer 130 are removed to form the first active layer 132, the protective layer 143, the first dielectric layer 131, and the first conductive layer 141, remaining photoresist layer 170 can be removed by a plasma dry degumming process.

The array substrate manufacturing method further includes:
forming a third insulation layer (not shown in the figures) on the protective layer 143 and the first conductive layer 141 and patterning the third insulation layer to form a second dielectric layer 191 and a first gate electrode insulation layer 192, wherein the second dielectric layer 191 at least overlaps with the first conductive layer 141, and the first gate electrode insulation layer 192 is located between the protective layer 143; and
forming a second metal layer (not shown in the figures) on the first gate electrode insulation layer 192 and the second dielectric layer 191, patterning the second metal layer to form a first gate electrode 194 and a second conductive layer 193. The first gate electrode 194 at least overlaps with the first gate electrode insulation layer 192. The second conductive layer 193 at least overlaps with the second dielectric layer 191.

FIG. 2f shows the structure forming the first gate electrode insulation layer 192, the second dielectric layer 191, the first gate electrode 194, and the second conductive layer 193, which includes: the underlay 110; the first insulation layer 120, the first dielectric layer 131, the first conductive layer 141, the second dielectric layer 191, the second conductive layer 193 sequentially located on the underlay 110; the first active layer 132, the protective layer 143, and the first gate electrode 194 sequentially located on the underlay 110 and the first insulation layer 120; the second insulation layer 180 covering the first dielectric layer 131, the first conductive layer 141, the second dielectric layer 191, the second conductive layer 193, the first active layer 132, the protective layer 143, and the first gate electrode 194. Projections of the first gate electrode 194 and the first active layer 132 on the underlay 110 at least partially overlap with each other.

Particularly, a deposition process, for example, an evaporation process, can be used to form a third insulation layer on the first active layer 132 and the first conductive layer 141, and the third insulation layer is patterned to form the second dielectric layer 191 and the first gate electrode insulation layer 192. The second dielectric layer 191 at least partially overlaps with the first conductive layer 141. The first gate electrode insulation layer 192 is located among the protective layer 143. Then, a deposition process such as an evaporation process can be used to form a second metal layer (not shown in the figures) on the first gate electrode insulation layer 192 and the second dielectric layer 191, and the second metal layer is patterned to form a first gate electrode 194 and a second conductive layer 193. The first gate electrode 194 at least overlaps with the first gate electrode insulation layer 192. The second conductive layer 193 at least overlaps with the second dielectric layer 191. The first gate electrode 194 can be a gate electrode corresponding to a first transistor of the first active layer 132. The first active layer 132 can be an active area (AA) of the first transistor. A material of the second insulation layer 180 and/or the third insulation layer can include oxide, for example, silicon dioxide (SiO₂), which is not specifically limited. The first transistor (TFT) corresponding to the first active layer 132 can be a switch TFT in the display panel.

Particularly, because the projections of the second conductive layer 193, the second dielectric layer 191, and the first conductive layer 141 on the underlay 110 at least partially overlap with one another, the second conductive layer 193, the second dielectric layer 191, and the first conductive layer 141 can form a capacitor structure. The capacitor structure can serve as a pixel capacitor in the pixel circuit. Because only the second dielectric layer 191 is disposed between the first conductive layer 141 and the second conductive layer 193, a distance between the first conductive layer 141 and the second conductive layer 193 is small such that a value of a formed capacitor structure is great. Using a capacitor structure with a great capacitor value can improve stability of a driver thin film transistor (DTFT) connected to the pixel circuit. In a light emission stage of the pixel, a level of a gate electrode of the DTFT transistor is lowered to mitigate flicker of the display panel. Furthermore, the first conductive layer 141, the second dielectric layer 191, and the second conductive layer 193 can be sequentially disposed on the first active layer 132. The first conductive layer 141, the second dielectric layer 191, and the second conductive layer 193 are located between a second source electrode 1951 and a second drain electrode 1952, which can save a space and prevent influence to other signal lines.

The array substrate manufacturing method further includes:
forming a second insulation layer 180 on the first gate electrode 194 and the second conductive layer 193;
forming first via holes 196 and second via holes 195 in the second insulation layer 180 and the first insulation layer 120;
forming a third metal layer on the second insulation layer 180; and
patterning the third metal layer to from a first source electrode 1961, a first drain electrode 1962, a second source electrode 1951, and a second drain electrode 1952;

The first source electrode 1961 and the first drain electrode 1962 are connected to the protective layer 143 through the first via holes 196 formed in the second insulation layer 180, and the second source electrode 1951 and the second drain electrode 1952 are connected to the second active layer 150 through the second via holes 195 formed in the second insulation layer 180 and the first insulation layer 120.

A projection of the first via holes 196 on the underlay 110 is located within a projection of the protective layer 143 on the underlay 110. A material of the transparent conductive layer 140 includes indium tin oxide (ITO) or indium gallium zinc oxide (IGZO).

FIG. 2g shows a structure forming the first via holes 196 and the second via holes 195, which includes: the underlay 110; the second active layer 150, the first insulation layer 120, the first dielectric layer 131, the first conductive layer 141, the second dielectric layer 191, the second conductive layer 193 sequentially disposed on the underlay 110, and the second gate electrode 160 disposed in the first insulation layer 120; the first active layer 132, the protective layer 143, and the first gate electrode 194 sequentially disposed on the underlay 110 and the first insulation layer 120; the second insulation layer 180 covering the first dielectric layer 131, the first conductive layer 141, the second dielectric layer 191, the second conductive layer 193, the first active layer 132, the protective layer 143, and the first gate electrode 194; the first via holes 196 defined through the second insulation layer 180 and extending to the protective layer 143; the second via holes 195 defined through the second insulation layer 180 and the first insulation layer 120 and extending to the second active layer 150.

Particularly, after the first gate electrode and after second conductive layer are formed on the second insulation layer, the first via holes 196 and the second via holes 195 can be formed in the second insulation layer 180 and/or the first insulation layer 120 by an etching process, for example, a wet-etching process. The first via holes 196 are defined through the second insulation layer 180 and extend to the protective layer 143, the second via holes 195 are defined through the second insulation layer 180 and the first insulation layer 120 and extend to the second active layer 150.

FIG. 2h shows the structure forming the first source electrode 1961, the first drain electrode 1962, the second source electrode 1951 and the second drain electrode 1952, which includes: the underlay 110; the second active layer 150, the first insulation layer 120, the first dielectric layer 131, the first conductive layer 141, the second dielectric layer 191, and the second conductive layer 193 sequentially located on the underlay 110, and the second gate electrode 160 located in the first insulation layer 120; the first active layer 132, the protective layer 143, and the first gate electrode 194 sequentially located on the underlay 110 and the first insulation layer 120; the second insulation layer 180 covering the first dielectric layer 131, the first conductive layer 141, the second dielectric layer 191, the second conductive layer 193, the first active layer 132, the protective layer 143, and the first gate electrode 194. The second source electrode 1951 and the second drain electrode 1952 are defined through the second insulation layer 180 and the first insulation layer 120 and are connected to the second active layer 150. The first source electrode 1961 and the first drain electrode 1962 are defined through the second insulation layer 180 and are connected to the protective layer 143.

Particularly, a third metal layer (not shown in the figures) can be formed on the second insulation layer 180. During formation of the third metal layer, a material of the third metal layer is filled in the first via holes 196 and the second via holes 195. After formation of the third metal layer, the third metal layer is patterned to form the first source electrode 1961, the first drain electrode 1962, the second source electrode 1951, and the second drain electrode 1952. The first source electrode 1961 and the first drain electrode 1962 are connected to the protective layer 143 through the first via holes 196 formed in the second insulation layer 180. The second source electrode 1951 and the second drain electrode 1952 are connected to the second active layer 150 through the second via holes formed in the second insulation layer 180 and the first insulation layer 120. A material of the third metal layer can be conductive material, for example, aluminum, tungsten or poly-silicon, which is not specifically limited.

The first via holes 196 and the second via holes 195 can be formed in the same process step to reduce a photomask and a process step to decrease the manufacturing cost. However, Because a depth of the second via holes 195 is greater than that of the first via holes 196, during formation of deep holes (for example, a plurality of the second via holes 195) and shallow holes (for example, a plurality of the first via holes 196) in the same process step by an etching process, a layer of the protective layer 143 is formed on the first active layer 132 to prevent over-etching from damaging the first active layer 132 during formation of the shallow holes, which can mitigate damages to the shallow holes during the etching process. Also, because the protective layer 143 employs transparent conductive metal oxide (for example, ITO/IZO), it can improve transmittance. Namely, by the method of the embodiment of the present application, a layer of the transparent conductive protective layer 143 is formed on the first active layer 132 to achieve simultaneous formation of the first via holes 196 and the second via holes 195, which can improve transmittance, save the cost, and improve a production rate.

Furthermore, because the protective layer 143 is configured to protect the first active layer 132 during simultaneous formation of the deep holes and the shallow holes, a projection of the first via holes 196 on the underlay 110 is located within a projection of the protective layer 143 on the underlay 110, namely, the first via holes 196 are completely on the protective layer 143 to protect the first active layer 132 of a lower layer during etching.

Furthermore, materials of the first conductive layer 141 and the protective layer 143 can be the same. For example, the material of the first conductive layer 141 and the protective layer 143 is indium tin oxide or indium gallium zinc oxide. The first conductive layer 141 and the protective layer 143 can be formed by the same mask in the same process step to further reduce a process and lower a manufacturing cost. Furthermore, similarly, materials of the second dielectric layer 191 and the third insulation layer are the same. For example, the material of the second dielectric layer 191 and the third insulation layer is oxide, and the second dielectric layer 191 and the third insulation layer are formed by the same mask in the same process step. The second conductive layer 193 and the first gate electrode 194 has the same material and are formed by the same mask in the same process step to further reduce a process and lower the manufacturing cost.

According to the above array substrate manufacturing method described by the embodiment of the present application, the present application further provides an array substrate, as shown in FIG. 2h, including: an underlay 110; a first insulation layer 120 disposed on the underlay 110; a first active layer disposed on the first insulation layer 120; a protective layer 143 disposed on the first active layer; a first gate electrode 194 disposed on first active layer and disposed at an interval from the protective layer 143; a second insulation layer 180 disposed on the first insulation layer 120, the first active layer, the protective layer 143, and the first gate electrode 194; and a first source electrode 1961 and a the first drain electrode 1962, wherein the first source electrode 1961 and the first drain electrode 1962 are connected to the protective layer 143 through first via holes 196 formed in the second insulation layer 180; wherein a material of the protective layer 143 includes indium tin oxide or indium gallium zinc oxide.

In the embodiment of the present application, disposing the transparent protective layer 143 on the first active layer 132 can protect the first active layer 132 during later formation of the first via holes 196 to improve the yield rate and reliability of the display panel. Also, using the transparent protective layer 143 can improve transmittance of the display panel.

The array substrate further includes:
a second active layer 150 disposed on the underlay 110, wherein the first insulation layer 120 covers the second active layer 150;
a second gate electrode 160 corresponding to the second active layer 150 and disposed in the first insulation layer 120; and the second source electrode 1951 and the second drain electrode 1952 connected to the second active layer 150 through second via holes formed in the second insulation layer 180 and the first insulation layer 120, wherein the second gate electrode 160 is located between the second source electrode 1951 and the second drain electrode 1952.

A material of the second active layer 150 includes low temperature polycrystalline oxide.

A material of the second insulation layer 180 and/or third insulation layer can include oxide, for example silicon dioxide (SiO₂), which has no specific limit.

The array substrate further includes:
a first dielectric layer 131, a first conductive layer 141, a second dielectric layer 191, and a second conductive layer 193 sequentially disposed on the first insulation layer 120, wherein the first conductive layer 141, the second dielectric layer 191, and the second conductive layer 193 are located between the second source electrode 1951 and the second drain electrode 1952;
wherein projections of the first conductive layer 141, the second dielectric layer 191, and the second conductive layer 193 on the underlay 110 at least partially overlap with one another, and a material of the first conductive layer 141 includes transparent conductive metal oxide.

The array substrate further includes a third insulation layer, and the third insulation layer is disposed between the first gate electrode 194 and the first active layer 132. The first dielectric layer 131 and the first active layer 132 are disposed in the same layer. The first conductive layer 141 and the protective layer 143 are disposed in the same layer. The second dielectric layer 191 and the first gate electrode insulation layer 192 are disposed in the same layer. The second conductive layer 193 and the first gate electrode 194 are disposed in the same layer.

In the embodiment of the present application, disposes the protective layer 143 on the first active layer 132. In the same process step, deep holes and shallow holes are formed, the protective layer 143 prevents over-etching the shallow holes from damaging a film layer (for example, the first active layer 132) below to achieve reduction of a number of the mask plates and the manufacturing cost while process stability and performance of the display panel are guaranteed.

Furthermore, by halftone process, a halftone mask plate can be used to form the photoresist layer 170 with different thicknesses on the transparent conductive layer 140 to reduce a number of the mask plates to further decrease the manufacturing cost.

Furthermore, because the transparent conductive layer 140 and the first active layer 132 can use a material such as IZO or IGZO, the material can be suitable for oxalic acid etching. Compared to removal of other material, for example, removing a part of a metal material (for example, the protective layer 143 is a metal material) requires an additional acid etching. However, removing the transparent conductive layer 140 and the oxide semiconductor layer 130 requires no changing machine and liquid, which reduces production time and improves production efficiency. Also, oxalic acid has a lower cost compared to metal acid (for example, Cu acid or A1 acid), which lowers the manufacturing cost.

As described above, by the array substrate of the embodiment of the present application, the first via holes 196 and the second via holes 195 are simultaneously formed without damaging the first active layer 132, which reduces process steps and manufacturing cost, increases transmittance to improve the yield rate and reliability of the display panel.

It should be understood that the array substrate of the embodiment of the present application, the structures forming assembling parts of the array substrate and the manufacturing process can refer to the above embodiments of the array substrate manufacturing method, which are not described repeatedly here.

According to the array substrate and the manufacturing method thereof as described in the above embodiment of the present application, the present application provides a display panel 200. The display panel 200 includes an opposite substrate 220 and any one of the abovementioned array substrate 210. The opposite substrate 220 is disposed opposite to the array substrate 210.

Particularly, the display panel 200 can be an organic light emitting diode (OLED) display panel, can also be a liquid crystal display panel (LCD), or a display panel of other type, which is not limited specifically.

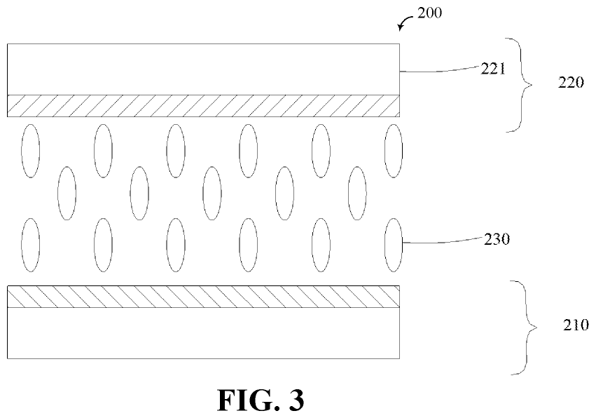

Furthermore, with reference to FIG. 3, the display panel 200 further includes:
an opposite substrate 220 disposed opposite to the array substrate 210; and
a liquid crystal layer 230 disposed between the array substrate 210 and the opposite substrate 220.

The opposite substrate 220 can be a color filter substrate.

Furthermore, It should be explained that FIG. 3 only shows the structure related to the embodiment of the present application. The display panel 200 of the present application can further include other assembly and/or structure for implementing complete functions of the display panel 200.

Particularly, with reference to FIG. 3, the display panel 200 can further include a color filter substrate disposed opposite to the array substrate 210. The color filter substrate includes an underlay substrate 221 and one or more thin films on the underlay substrate 221. The one or more thin films can be conductive thin films and/or functional thin films. The color filter substrate can include the underlay substrate 221 and the color filter layer (RGB, not shown in the figures) and a planarization layer (not shown in the figures) on the underlay substrate 221. The color filter layer (RGB) can include a red (R) filtering layer (not shown in the figures), a green (G) filtering layer (not shown in the figures), and a blue (B) filtering layer (not shown in the figures). Using the display panel 200 of the embodiment of the present application reduces process steps and manufacturing cost to improve the yield rate and reliability of the display panel.

As described above, the present application provides an array substrate, a manufacturing method thereof and a display panel. The array substrate includes: an underlay; a first insulation layer disposed on the underlay; a first active layer disposed on the first insulation layer; a protective layer disposed on the first active layer; a first gate electrode disposed on the first active layer and disposed at an interval from the protective layer; a second insulation layer disposed on the first insulation layer, the first active layer, the protective layer, and the first gate electrode; and a first source electrode and a first drain electrode, wherein the first source electrode and the first drain electrode are connected to the protective layer through first via holes defined in the second insulation layer; wherein a material of the protective layer includes indium tin oxide or indium gallium zinc oxide. Disposing a transparent protective layer on the first active layer can protect the first active layer during later formation of first via holes to improve yield rate reliability of the display panel. Also, using the transparent protective layer can improve transmittance of the display panel.

The above descriptions are only the preferred embodiments of the present invention, and are not intended to limit the present invention. Any modifications, equivalents, and improvements made within the spirit and scope of the present invention should be included in the protective extent of the present invention.

What is claimed is:

1. An array substrate, comprising:
an underlay;
a first insulation layer disposed on the underlay;
a first active layer disposed on the first insulation layer;
a protective layer disposed on the first active layer;
a first gate electrode disposed on the first active layer and disposed at an interval from the protective layer;
a second insulation layer disposed on the first insulation layer, the first active layer, the protective layer, and the first gate electrode; and
a first source electrode and a first drain electrode, wherein the first source electrode and the first drain electrode are connected to the protective layer through first via holes defined in the second insulation layer;
wherein a material of the protective layer comprises indium tin oxide or indium gallium zinc oxide.

2. The array substrate according to claim 1, wherein the array substrate further comprises:
a second active layer disposed on the underlay, wherein the first insulation layer covers the second active layer;
a second gate electrode corresponding to the second active layer and disposed in the first insulation layer; and
a second source electrode and a second drain electrode, wherein the second source electrode and the second drain electrode are connected to the second active layer through second via holes defined in the second insulation layer and the first insulation layer, and the second gate electrode are located between the second source electrode and the second drain electrode.

3. The array substrate according to claim 2, wherein the array substrate further comprises:
a first dielectric layer, a first conductive layer, a second dielectric layer, and a second conductive layer sequentially disposed on the first insulation layer, wherein the first conductive layer, the second dielectric layer, and the second conductive layer are located between the second source electrode and the second drain electrode;
wherein projections of the first conductive layer, the second dielectric layer, and the second conductive layer on the underlay at least partially overlap with one another, and a material of the first conductive layer comprises transparent conductive metal oxide.

4. The array substrate according to claim 3, wherein the array substrate further comprises a first gate electrode insulation layer, the first gate electrode insulation layer is disposed between the first gate electrode and the first active layer, the first dielectric layer and the first active layer are disposed in a same layer, the first conductive layer and the protective layer are disposed in a same layer, the second dielectric layer and the first gate electrode insulation layer are disposed in a same layer, and the second conductive layer and the first gate electrode are disposed in a same layer.

5. An array substrate manufacturing method, comprising:
providing an underlay;
forming a first insulation layer on the underlay;
forming an oxide semiconductor layer on the first insulation layer;
forming a transparent conductive layer on the oxide semiconductor layer, wherein a material of the transparent conductive layer comprises indium tin oxide or indium gallium zinc oxide;
forming a photoresist layer on the transparent conductive layer, and patterning the photoresist layer to form at least one first aperture; and
etching and removing a portion of the transparent conductive layer corresponding to a location of the first aperture to form a protective layer.

6. The array substrate manufacturing method according to claim 5, wherein the first insulation layer comprises a gate electrode insulation layer and an interlayer insulation layer, before the step of forming the first insulation layer on the underlay, the method further comprises: forming a second active layer on the underlay;
the step of forming the first insulation layer on the underlay comprises:
forming a gate electrode insulation layer on the second active layer;
forming a second gate electrode on the gate electrode insulation layer; and
forming an interlayer insulation layer on the second gate electrode.

7. The array substrate manufacturing method according to claim 6, wherein before the step of patterning the photoresist layer to form the at least one first aperture, the method further comprises:
patterning the photoresist layer to form at least one second aperture and a plurality of third apertures;
etching and removing portions of the transparent conductive layer corresponding to the at least one second aperture and the third apertures respectively to form a first conductive layer and a first metal layer; and
etching and removing portions of the oxide semiconductor layer corresponding to the at least one second aperture and the third apertures respectively to form a first active layer and a first dielectric layer, wherein the first dielectric layer and a first conductive layer layer are stacked and disposed on the underlay, and the first active layer and the first metal layer layer are stacked and disposed on the underlay.

8. The array substrate manufacturing method according to claim 7, wherein the step of wet-etching and removing the transparent conductive layer and the step of wet-etching and removing the oxide semiconductor layer are implemented simultaneously, a material of the oxide semiconductor layer comprises indium tin oxide or indium gallium zinc oxide, and an etchant for the wet-etching comprises oxalic acid.

9. The array substrate manufacturing method according to claim 7, wherein the step of patterning the photoresist layer to form the at least one first aperture comprises:
patterning the photoresist layer, removing the photoresist layer on the first conductive layer, and partially removing the photoresist layer on the first metal layer to form the first aperture.

10. The array substrate manufacturing method according to claim 7, wherein the array substrate manufacturing method further comprises:
forming a third insulation layer on the protective layer and the first conductive layer and patterning the third insulation layer to form a second dielectric layer and a first gate electrode insulation layer, wherein the second dielectric layer at least partially overlaps with the first conductive layer, and the first gate electrode insulation layer is located among the protective layer; and
forming a second metal layer on the first gate electrode insulation layer and the second dielectric layer and patterning the second metal layer to form a first gate electrode and a second conductive layer, wherein the first gate electrode at least partially overlaps with the first gate electrode insulation layer, and the second conductive layer at least partially overlaps with the second dielectric layer.

11. The array substrate manufacturing method according to claim 10, wherein the array substrate manufacturing method further comprises:
forming a second insulation layer on the first gate electrode and the second conductive layer;
forming first via holes and second via holes in the second insulation layer and the first insulation layer;
forming a third metal layer on the second insulation layer; and
patterning the third metal layer to form a first source electrode, a first drain electrode, a second source electrode, and a second drain electrode;
wherein the first source electrode and the first drain electrode are connected to the protective layer through the first via holes formed in the second insulation layer, and the second source electrode and the second drain electrode are connected to the second active layer through the second via holes formed in the second insulation layer and the first insulation layer.

12. A display panel, comprising an opposite substrate and the array substrate according to claim 1, wherein the opposite substrate and the array substrate are disposed oppositely at an interval.

13. The display panel according to claim 12, wherein the array substrate further comprises:
a second active layer disposed on the underlay, wherein the first insulation layer covers the second active layer;
a second gate electrode corresponding to the second active layer and disposed in the first insulation layer; and
a second source electrode and a second drain electrode, wherein the second source electrode and the second drain electrode are connected to the second active layer through second via holes defined in the second insulation layer and the first insulation layer, and the second gate electrode are located between the second source electrode and the second drain electrode.

14. The display panel according to claim 13, wherein the array substrate further comprises:
a first dielectric layer, a first conductive layer, a second dielectric layer, and a second conductive layer sequentially disposed on the first insulation layer, wherein the first conductive layer, the second dielectric layer, and the second conductive layer are located between the second source electrode and the second drain electrode;
wherein projections of the first conductive layer, the second dielectric layer, and the second conductive layer on the underlay at least partially overlap with one another, and a material of the first conductive layer comprises transparent conductive metal oxide.

15. The display panel according to claim 14, wherein the array substrate further comprises a first gate electrode insulation layer, the first gate electrode insulation layer is disposed between the first gate electrode and the first active layer, the first dielectric layer and the first active layer are disposed in a same layer, the first conductive layer and the protective layer are disposed in a same layer, the second dielectric layer and the first gate electrode insulation layer are disposed in a same layer, and the second conductive layer and the first gate electrode are disposed in a same layer.

16. The array substrate according to claim 1, wherein a material of the first active layer comprises indium tin oxide or indium gallium zinc oxide.

17. The array substrate according to claim 1, wherein a projection of the first via holes on the underlay is located within a projection of the protective layer on the underlay.

18. The array substrate according to claim 2, wherein a material of the second active layer comprises low temperature polycrystalline oxide.

19. The array substrate according to claim 2, wherein an organic layer, an inorganic layer, and a first buffer layer are sequentially disposed on the underlay and are located between the underlay and the second active layer.

20. The array substrate according to claim 1, wherein the first insulation layer comprises a gate electrode insulation layer, an interlayer insulation layer, and a second buffer layer.
